(19) United States
(12) Patent Application Publication
(10) Pub. No.: US 2010/0110650 A1
(43) Pub. Date: May 6, 2010

(54) Soldering Strategies for Printed Circuit Board Assemblies

(76) Inventors: Martha A. Maxwell, Milwaukee, WI (US); Corey A. Peterson, Grafton, WI (US); John N. Bluma, Milwaukee, WI (US)

Correspondence Address: ROCKWELL AUTOMATION, INC. / WHD;ATTENTION: SUSAN M. DONAHUE, PATENT DEPT. / E-7F19, 1201 SOUTH SECOND STREET, MILWAUKEE, WI, 53204, US

(21) Appl. No.: 12/262,710

(22) Filed: Oct. 31, 2008

(51) Int. Cl. H05K 3/34; H05K 7/00

(52) U.S. Cl. 361/777; 29/840

(57) ABSTRACT

Disclosed herein is a method for forming solder joints including providing a printed circuit board having a first outer surface, a second outer surface opposite the first outer surface, and a plurality of conductive interconnect traces. The printed circuit board supports on the first outer surface at least one electronic component having a plurality of leads, and further includes a plurality of through-hole clusters. Each through-hole cluster is associated with a single lead and includes a central hole portion surrounded by a plurality of other hole portions. A plurality of solder joints is formed by subsequently moving the printed circuit board over a wave soldering tank filled with solder. Each solder joint is formed between a respective lead inserted in the central hole portion of a respective through-hole cluster and a corresponding one of the plurality of conductive interconnect traces. Each solder joint is formed by solder which is wicked up by the through-hole cluster to extend from the second surface to the first surface.

### CROSS-REFERENCE TO RELATED APPLICATIONS

Not Applicable

### STATEMENT REGARDING FEDERALLY SPONSORED RESEARCH OR DEVELOPMENT

Not Applicable

### FIELD OF THE INVENTION

The present invention relates to soldering strategies for printed circuit board assemblies, including forming a solder joint by wicking solder through a through-hole cluster.

### BACKGROUND OF THE INVENTION

Variable frequency drive controllers, also known as AC (alternating current) drives, are power conversion devices that are used to drive motors or other devices. Generally, an AC drive receives power from an AC power grid at a fixed frequency, converts this power to an intermediate DC power across an intermediate bus using a rectifier circuit, then converts the intermediate DC power to a controlled frequency, quasi-sinusoidal AC power using a switched inverter circuit. The rectifier circuit typically includes diodes, the inverter circuit typically includes semiconductor switches such as insulated-gate bipolar transistors (IGBTs), and the drive further includes capacitors and other electronic components.

The physical form of an AC drive can vary according to the power required by the driven device. For example, AC drives may support loads ranging from a fraction of a horsepower (HP) up to thousands of horsepower. In particular, a high horsepower AC drive, such as for example a 480 Volt 75 HP drive, is typically formed as a power structure consisting of a plurality of components connected together with multiple bus bars in order to handle the large currents required. The components of a typical power structure include a rectifying module, an output power module, a gate driver board, multiple electrolytic capacitors, snubber capacitors, and the bus bars. On the other hand, an AC drive having a lower horsepower rating can generally be formed on a printed circuit board (PCB) as a PCB assembly. The PCB supports and interconnects the various electronic components making up the AC drive and normally consists of one or more layers of laminated insulating sheets with etched copper patterns or traces providing interconnections for electrical signals between the electronic components supported thereon.

Different constructions exist for mounting components to a PCB. In a “through-hole” construction, the electronic components are mounted on a first (e.g. top) surface of the PCB, holes are drilled through the board to permit component leads to extend through the board, and etched copper interconnect traces (including pads) are formed on a second (e.g. bottom) surface and on other intermediate surfaces of any multiple layers. These through-holes are also known as vias. A soldering process provides a connection between each respective lead and a corresponding copper pad on the bottom surface. In a “surface mount” construction, the electronic components are mounted on the same surface as the copper interconnect pads, and the components leads are respectively connected to a corresponding copper interconnect pad. Often, through-hole and surface-mount constructions are combined in a single PCB because some required components are available only in surface-mount packages, while others are available only in through-hole packages. Another reason to use both constructions is that through-hole mounting can provide needed strength for components likely to endure physical stress, while components that are expected to go untouched will typically take up less space using surface-mount techniques.

When using a through-hole construction, soldering of the components to the PCB can be performed as part of a manual soldering process or can preferably be performed as a wave soldering process in which all components are soldered essentially simultaneously. Wave soldering is significantly more efficient and cost effective than manual soldering, and is generally the soldering method of choice for high production circuit boards. This is a continuous process in which circuit boards are passed over a wave of molten solder. The solder wicks up through the through-holes containing the component leads to form solder joints. This process lends itself to automation, as the parts are simply loaded onto a conveyor which in turn passes the parts over a wide wave of solder. Advances in PCB technology, such as double-sided boards and mixed technology assemblies, have allowed intricate and complex circuits to be implemented in a smaller footprint.

As noted above, high HP AC drives are typically formed as separate modules which are connected together. While attempts have been made to form high HP AC drives as PCB assemblies, the required high current capabilities of the drive dictates that the copper interconnect traces are sufficiently large, resulting in so called “heavy copper” PCBs and/or the use of multi-layer boards. These high HP AC drives also typically require discrete electronic components such as capacitors which have large lead dimensions, thereby requiring a large through-hole to match the lead dimension. Thus PCB assemblies for high HP AC drives do not lend themselves to a wave soldering process, since the through-holes are too large for the wave soldering process to adequately achieve solder hole fill. Accordingly, wave soldering of heavy copper AC drive PCBs or other high power conversion or control devices has not previously been successfully achieved.

### BRIEF SUMMARY OF THE INVENTION

Accordingly, it would be desirable to manufacture high power conversion or control devices, such as AC drives, on heavy copper printed circuit boards using a wave soldering process which achieves reliable solder joints.

In at least some embodiments, the present invention relates to a printed circuit board assembly including a printed circuit board having a first outer surface, a second outer surface opposite the first outer surface, and a plurality of conductive interconnect traces. The printed circuit board supports on the first outer surface at least one electronic component having a plurality of leads. The printed circuit board further includes a plurality of through-hole clusters, wherein each through-hole cluster is associated with a respective lead and includes a central hole portion and a plurality of adjacent hole portions. A plurality of solder joints are formed, wherein each solder joint is formed between a respective lead inserted in the central hole portion of a respective through-hole cluster and a corresponding one of the plurality of conductive interconnect traces.

In at least some embodiments, the present invention relates to a method for wave soldering electronic components to a printed circuit board. The method includes providing a printed circuit board having a first outer surface, a second outer surface opposite the first outer surface, and a plurality of conductive interconnect traces, the printed circuit board supporting on the first outer surface at least one electronic component having a plurality of leads, the printed circuit board further including a plurality of through-hole clusters, wherein each through-hole cluster is associated with a single lead and includes a central hole portion surrounded by a plurality of other hole portions. The method further includes forming a plurality of solder joints by subsequently moving the printed circuit board over a wave soldering tank filled with solder, each solder joint formed between a respective lead inserted in a central hole portion of a respective through-hole cluster and a corresponding one of the plurality of conductive interconnect traces, wherein each solder joint is formed by solder which is wicked up by the through-hole cluster to extend from the second surface to the first surface.

Other embodiments, aspects, features, objectives and advantages of the present invention will be understood and appreciated upon a full reading of the detailed description and the claims that follow.

### BRIEF DESCRIPTION OF THE DRAWINGS

Embodiments of the invention are disclosed with reference to the accompanying drawings and are for illustrative purposes only. The invention is not limited in its application to the details of construction or the arrangement of the components illustrated in the drawings. The invention is capable of other embodiments or of being practiced or carried out in other various ways. Like reference numerals are used to indicate like components. In the drawings:

FIG. 1 is a top view of an exemplary AC drive printed circuit board assembly in accordance with at least some embodiments of the invention;

FIG. 2 is an illustration of another exemplary through-hole cluster for an electronic component such as one type of capacitor;

FIG. 3 is an illustration of another exemplary through-hole cluster for an electronic component such as another type of capacitor;

FIG. 4 is an illustration of another exemplary through-hole cluster for an electronic component such as another type of capacitor;

FIG. 5 is an illustration of another exemplary through-hole cluster for an electronic component such as a resistor;

FIG. 6 is an illustration of an exemplary flower configuration type through-hole cluster;

FIG. 7 is an illustration of another exemplary flower configuration type through-hole cluster;

FIG. 8 is an illustration showing the hole sizes for the through-hole cluster of FIG. 7;

FIG. 9 is an illustration of solder joints formed with leads of power resistors using through-hole clusters similar to that illustrated in FIG. 2; and

FIG. 10 is an illustration of solder joints formed with leads of power resistors using through-hole clusters similar to that illustrated in FIG. 7.

### DETAILED DESCRIPTION OF THE PREFERRED EMBODIMENT

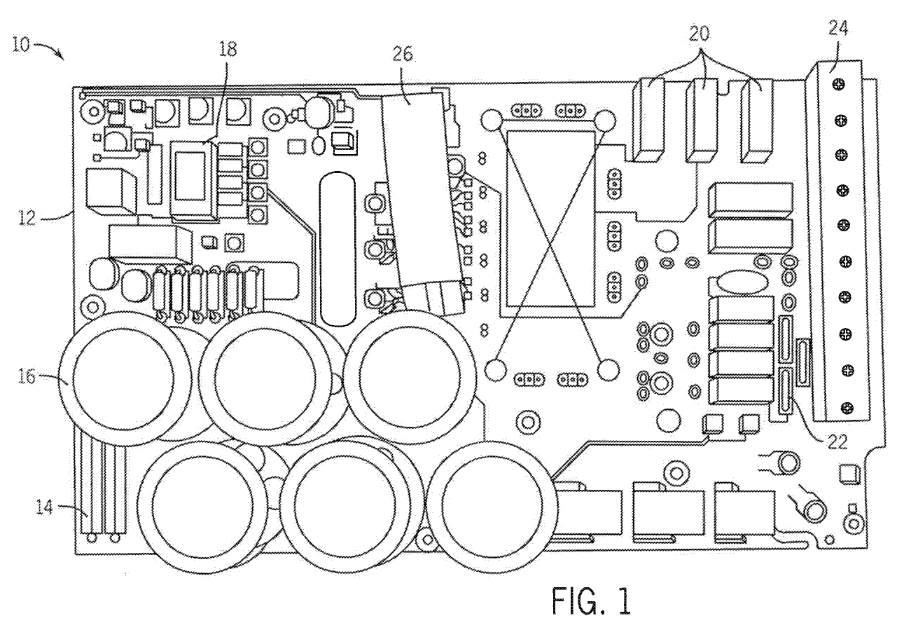

Referring to FIG. 1, an exemplary AC drive printed circuit board assembly 10 is illustrated which includes a variety of electronic components supported on a first (top) surface of a printed circuit board (PCB) 12, which can be a multi-layer circuit board. The electronic components include for example, a plurality of power resistors 14, capacitors 16, transformer 18, current sensors 20, metal oxide varistors (MOVs) 22, a terminal connector 24, a ribbon cable 26, and others. The opposite surface of the PCB (not shown) includes a plurality of conductive interconnect traces, preferably of copper. These traces include a plurality of pads, which respectively connect to leads of one or more of the electronic components on the top surface. The AC drive can be a high HP drive, for example, a 480 Volt 75 HP AC drive, and the printed circuit board assembly is preferably a heavy copper multi-layer circuit board, e.g., one that includes more than approximately 2 ounces of copper per layer.

In at least one embodiment, the printed circuit board 12 has at least five layers, the inner layers each have at least four ounces of copper interconnect traces per layer, and the two outer layers each have at least one ounces of copper interconnect traces per layer.

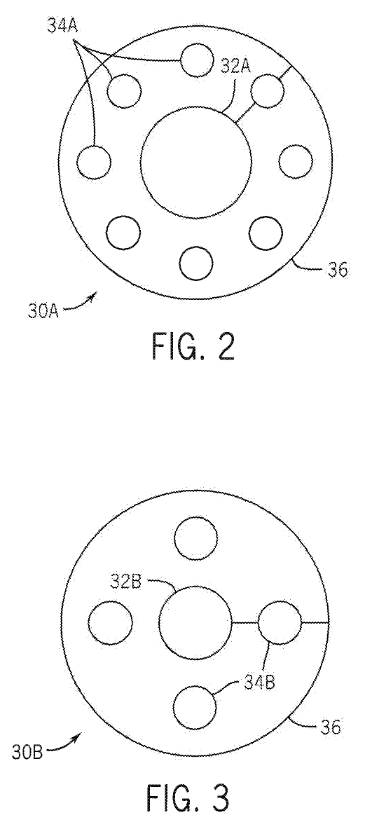

Some of the electronic components making up the drive are through-hole components which can be soldered to the PCB preferably using a wave solder process, as more fully described below. For at least some of these through-hole components, their leads are each respectively inserted into a corresponding central hole portion of a through-hole cluster (a single lead in a single central hole portion). As shown in FIG. 2, an exemplary through-hole cluster 30A includes a plurality of through-holes (also known as vias) with a central hole portion 32A and a plurality of adjacent or surrounding hole portions 34A (not all labeled) which aid in the soldering process. The adjacent hole portions 34A and the central hole portion 32A wick up solder from a wave solder tank from the bottom surface to the top surface of the PCB 12, with the adjacent hole portions 34A essentially providing additional surface area to induce capillary action and aid in the wicking up process. The adjacent hole portions 34A also act as heat pipes to provide additional heat and temperature stabilization for the solder. In this manner, good solder joints can be formed and complete hole fill can be achieved. Specifically, the solder joints are formed between a respective component lead and its corresponding conductive interconnect trace (or pad) formed on the other side of the printed circuit board 12.

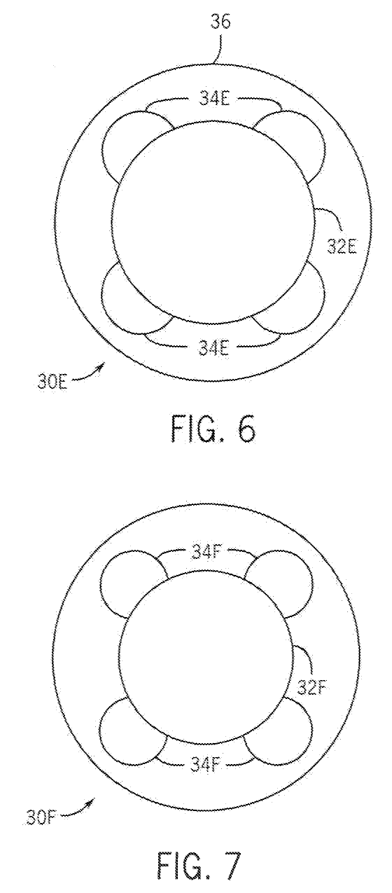

FIGS. 3-7 show other exemplary through-hole clusters 30B-30F, each through-hole cluster including a corresponding central hole portion 32B-32F and a corresponding plurality of other adjacent hole portions 34B-34F. Each central hole portion 32A-32F is typically substantially centered with respect to its corresponding interconnect trace or pad 36 formed on the second surface, which pads can take a variety of shapes. The through-hole clusters 30A-30F can be divided into different types, as shown in FIGS. 2-7. For example, as shown in FIGS. 2-5, a first through-hole cluster type is where the central hole portion 32A-32D is separate from its corresponding plurality of adjacent hole portions 34A-34D, with PCB material in between. Alternatively, as shown in FIGS. 6-7, another through-hole cluster type is where the central hole portion 32E-32F and the corresponding surrounding hole portions 34E-34F overlap to form a flower configuration, e.g., a configuration with scalloped edges. Varying amounts of overlap are contemplated as FIGS. 6 and 7 illustrate. In both types of through-hole clusters, the surface area of the through-hole cluster forming the solder joint is increased over the surface area of a central hole alone.

The size of a central hole portion is generally determined by the size of a corresponding electronic lead which needs to be inserted in that central hole portion, and its shape can vary. Further, the size, shape and number of the adjacent hole portions can vary. Preferably, the diameter of one or more holes in the plurality of adjacent hole portions 34A-34F is in the range of approximately 0.020 to 0.035 inches (i.e. 20 to 35 mils), and these hole portions need not be the same size as the central hole portion or each other. Generally, the larger the central hole portion, the greater number of surrounding hole portions required to achieve appropriate hole fill and thus a reliable solder joint.

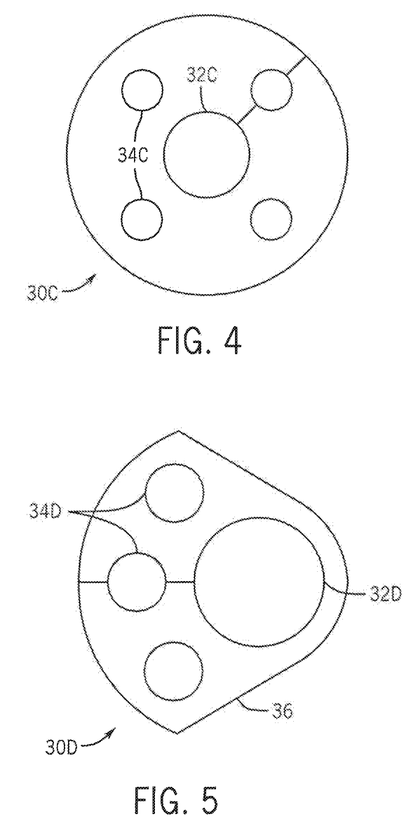

With respect to preferred sizes, FIG. 2 illustrates the through-hole cluster 30A with the central hole portion 32A having a size of 0.078 inches, and with the eight equally spaced hole portions 34A surrounding the central hole portion (also called a ring of vias) each having a size of 0.024 inches. FIG. 3 illustrates the through-hole cluster 30B with the central hole portion 32B having a size of 0.040 inches, and with the four equally spaced surrounding hole portions 34B each having a size of 0.024 inches. FIG. 4 illustrates the through-hole cluster 30C with a central hole portion 32C having a size of 0.051 inches, and with the four equally spaced surrounding hole portions 34C each having a size of 0.024 inches. The through-hole clusters configured as shown in FIGS. 2, 3, and 4 can be used to attach leads of various capacitors of the PCB assembly 10. Clearly other sizes of central hole portions and surrounding hole portions are contemplated, and the surrounding hole portions need not be equally spaced. FIG. 5 illustrates the through-hole cluster 30D which is meant for a lead of a power resistor, with a central hole portion 32D having a size of 0.057 inches, and with the three adjacent hole portions 34D each having a size of 0.024 inches. As shown, a distance between a central hole portion and the adjacent hole portions is preferably approximately 0.010 inches to 0.015 inches (with a tolerance of plus or minus 0.004 inches), and a distance between one of the adjacent hole portions and an outer pad edge 36 is preferably approximately 0.015 inches (with a tolerance of plus or minus 0.004 inches).

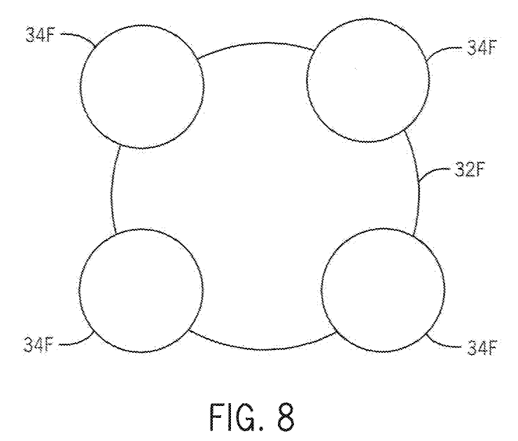

FIG. 8 is an illustration showing the through-hole cluster 30F of FIG. 7, and specifying the hole sizes. In particular, through-hole cluster 30F includes a central hole portion 32F having a size of 0.035 inches (35 mils), and four adjacent hole portions 34F each having a size of 0.014 inches (14 mils). Note that these hole sizes are the same for the through-hole cluster 30E shown in FIG. 6, with a different amount of overlap between the central hole portion and the others. In practice, the outer surrounding hole portions 34F are preferably formed, such as by drilling, prior to forming the overlapping central hole portion 32F.

The hole portions forming the through-hole cluster in the PCB 12 can be constructed by drilling the PCB 12 using tiny drill bits which can be made of solid tungsten carbide for example. Such drilling can be performed by automated drilling machines with controlled placement capabilities, to control the size and location of the desired holes. If very small holes are required, drilling with mechanical bits can be costly because of high rates of wear and breakage. In this case, the hole portions of the through-hole cluster can be formed by lasers. The holes formed are typically cylindrical in shape, although this not need be the case. Oval or elongated and other shaped holes and hole portions are also contemplated. The walls of some of the holes, for boards with two or more layers, can be plated with copper to form plated-through holes that electrically connect the conducting layers of the PCB 12.

The solder joints of the through-hole components supported on PCB 12 are preferably formed using a selective wave solder system and process in which the PCB assembly 10 (PCB 12 and supported electronic components) is moved, using a conveyor system at a predetermined speed, to different locations or stages where different processing activities occur. As a general overview, in the wave solder process, flux is applied, one or more heating stages occur, and then solder is applied via a “wave” to the bottom surface of the printed circuit board. Appropriate heating is required to allow the flux to remain within a desired temperature range such that the flux remains active (does not become exhausted) for the appropriate amount of time. Further, appropriate heating allows the electronic components to be heated in a manner that prevents excessive heat stress, yet allows the solder to be applied at an appropriate temperature. Parameters relating to the various process stages are preferably selected by a teaching process, which determines an appropriate conveyor speed and appropriate heating steps though evaluation of time vs. temperature graphs of the various layers of a PCB assembly 10 during one or more trial runs.

In an exemplary wave solder process for PCB assembly 10, using a commercially available wave solder system, an appropriate conveyor speed is determined to be approximately 82 centimeters per minute. At a first process stage, a flux is applied to both sides of the circuit board assembly 10 prior to the heating stages.

In a first heating stage, a first bottom side preheater is set to 130 degrees C. In a second heating stage, a second bottom side preheater is set to 150 degrees C. and a top side preheater is set at a 40% on duty cycle. In a third heating stage, a third bottom side preheater is set to 200 degrees C. and a top side preheater is set to a 60% on duty cycle. A solder which is preferably lead-free is then applied from a solder wave tank, and the solder is wicked up into the through-hole clusters to form solder joints to secure the supported electronic components. A preferred solder tank temperature is 270 degrees C. The wave solder system is preferably operated under the control of a control system, which controls the conveyor speed and heating stages. During automated production, the conveyor system will move to each of the stored process stages and the pre-programmed action will be conducted.

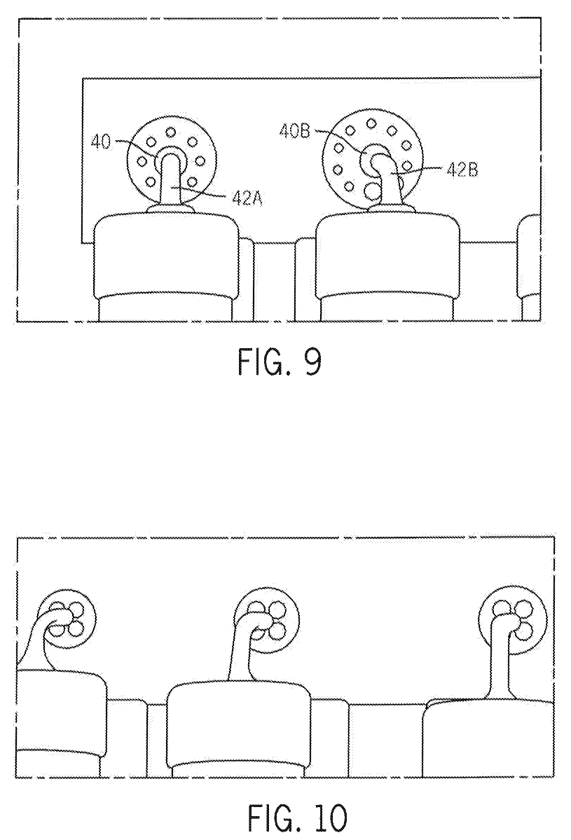

Using the above processing parameters, and the through-hole clusters such as illustrated and described above for at least some of the electronic components, acceptable solder joints are formed for the AC drive. During the soldering stage, solder is wicked up through the through-hole clusters from the bottom surface of PCB assembly 10 to the top surface to form solder joints 40A, 40B such are shown in FIGS. 9 and 10, which illustrate both non-overlapping and overlapping types of through-hole clusters.

In particular, FIG. 9 illustrates on the left the solder joint 40A for a lead 42A of a power resistor using a through-hole cluster similar to that illustrated in FIG. 2, wherein surrounding holes each have a diameter of 0.020 inches and lead 42A is inserted in the central hole. Similarly, illustrated on the right is the solder joint 40B formed in a through-hole cluster wherein the surrounding holes each have a diameter of 0.030 inches and a lead 42B is inserted in the central hole. Further, FIG. 10 is an illustration of solder joints formed in respective flower type through-hole clusters having varying degrees of overlap of the hole portions. Using varying forms and sizes of through-holes such as shown in FIGS. 9 and 10 allow the solder joints to be examined and an optimal design determined for one or more through-hole clusters. As shown, complete hole fill can be achieved resulting in reliable solder joints.

In this manner, the AC drive can be formed as a printed circuit board assembly using an automated wave soldering process or other soldering process wherein the solder is wicked through a through-hole cluster to form a solder joint. The printed circuit board assembly provides a reduction in size and weight for the AC drive as compared to the AC drive being constructed as a power structure having multiple components. Clearly, the same through-hole constructions can be beneficial in the assembly of other devices, specifically other high power devices, such as other power conversion devices (e.g. DC drives) and power control devices. The PCB assembly construction provides savings, improves process time, and at least in the case of a wave soldering process, improves manufacturability by allowing a wider process window for the wave soldering process.

It is specifically intended that the present invention not be limited to the embodiments and illustrations contained herein, but include modified forms of those embodiments including portions of the embodiments and combinations of elements of different embodiments as come within the scope of the following claims.

We claim:

1. A printed circuit board assembly comprising,
a printed circuit board having a first outer surface, a second outer surface opposite the first outer surface, and a plurality of conductive interconnect traces, the printed circuit board supporting on the first outer surface at least one electronic component having a plurality of leads, the printed circuit board further including a plurality of through-hole clusters, wherein each through-hole cluster is associated with a respective lead and includes a central hole portion and a plurality of adjacent hole portions, wherein a plurality of solder joints are formed, wherein each solder joint is formed between a respective lead inserted in the central hole portion of a respective through-hole cluster and a corresponding one of the plurality of conductive interconnect traces.

2. The printed circuit board assembly of claim 1, further wherein the solder extends substantially from the second surface to the first surface through each of the plurality of through-hole clusters.

3. The printed circuit board assembly of claim 1, wherein a diameter of each central hole portion is slightly larger than a width of a corresponding lead.

4. The printed circuit board assembly of claim 1, wherein a diameter of each hole portion in the plurality of adjacent hole portions is in the range of approximately 0.020 to 0.035 inches.

5. The printed circuit board assembly of claim 1, wherein the solder joint is formed by a wave soldering process.

6. The printed circuit board assembly of claim 1, wherein the plurality of conductive traces is copper.

7. The printed circuit board assembly of claim 1, wherein the at least one electronic component includes one or more capacitors and variable resistors.

8. The printed circuit board assembly of claim 1, wherein the printed circuit board is a multi-layer circuit board.

9. The printed circuit board assembly of claim 8, wherein the printed circuit board has at least five layers, the inner layers each have at least four ounces of copper interconnect traces per layer, and the two outer layers each have at least one ounce of copper interconnect traces per layer.

10. The printed circuit board assembly of claim 1, wherein for at least one of the plurality of through-hole clusters, the central hole portion and the plurality of adjacent hole portions in that through-hole cluster form a flower configuration.

11. The printed circuit board assembly of claim 1, wherein for at least one of the plurality of through-hole clusters, the central hole portion and the plurality of adjacent hole portions in that through-hole cluster do not overlap.

12. A power control or conversion device comprising the printed circuit board assembly of claim 1.

13. A power control or conversion device comprising,
a printed circuit board having a first outer surface, a second outer surface opposite the first outer surface, and a plurality of copper pads, the printed circuit board supporting on the first outer surface at least one electronic component having a plurality of leads, the printed circuit board further including a plurality of through-hole clusters, wherein each through-hole cluster is associated with a single respective lead and includes a central hole and a plurality of surrounding holes, wherein a plurality of solder joints are formed by a wave soldering process, wherein each solder joint is formed between a respective lead inserted in the central hole of a respective through-hole cluster and a corresponding one of the plurality of copper pads.

14. The power device of claim 13 further wherein the solder extends substantially from the second surface to the first surface through each of the through-hole clusters.

15. The power device of claim 13, wherein a diameter of each central hole is slightly larger than a width of a corresponding lead.

16. A method for wave soldering at least one electronic component to a printed circuit board, the method comprising:
providing a printed circuit board having a first outer surface, a second outer surface opposite the first outer surface, and a plurality of conductive interconnect traces, the printed circuit board supporting on the first outer surface at least one electronic component having a plurality of leads, the printed circuit board further including a plurality of through-hole clusters, wherein each through-hole cluster is associated with a respective lead and includes a central hole portion surrounded by a plurality of other hole portions, and
forming a plurality of solder joints by subsequently moving the printed circuit board over a wave soldering tank filled with solder, each solder joint formed between a respective lead inserted in the central hole portion of a respective through-hole cluster and a corresponding one of the plurality of conductive interconnect traces, wherein each solder joint is formed by solder which is wicked up by the through-hole cluster.

17. The method of claim 16, further including spraying flux on one or both sides of the printed circuit board prior to forming the plurality of solder joints.

18. The method of claim 16, further including one or more heating steps prior to forming the plurality of solder joints.

19. The method of claim 18, wherein the one or more heating steps include a first preheating step and a second heating step at a higher temperature.

20. The method of claim 18, further including a third heating step after the second heating step.
